(19) United States
(12) Patent Application Publication
(10) Pub. No.: US 2024/0117152 A1
(43) Pub. Date: Apr. 11, 2024

(54) NOVEL ORGANOSILICON COMPOUND, NOVEL CROSSLINKING AGENT, CURABLE COMPOSITION, PREPREG, MULTILAYER BODY, METAL CLAD LAMINATE AND WIRING BOARD

(71) Applicant: AGC Inc., Tokyo (JP)

(72) Inventors: Tsukasa USUDA, Chiyoda-ku (JP); Yoshitomi MORIZAWA, Chiyoda-ku (JP); Kazumi HASHIMOTO, Chiyoda-ku (JP); Ryosuke KAMITANI, Chiyoda-ku (JP)

(73) Assignee: AGC Inc., Tokyo (JP)

(21) Appl. No.: 18/510,837

(22) Filed: Nov. 16, 2023

Related U.S. Application Data
(63) Continuation of application No. PCT/JP2022/014004, filed on Mar. 24, 2022.

(30) Foreign Application Priority Data
Jun. 4, 2021 (JP) 2021-094354

(51) Int. Cl. C08K 5/5425; C08J 5/24

(52) U.S. Cl. CPC C08K 5/5425; C08J 5/244; C08J 2371/02

(57) ABSTRACT

An organosilicon compound is represented by the following formula (1TQ):

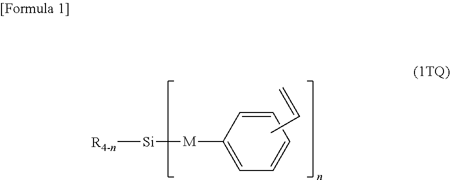

in which M is a single bond or an optionally substituted alkylene group having 1 to 20 carbon atoms; the benzene ring optionally has a substituent; the vinyl group is attached to the benzene ring at any position; n is an integer of 3 or 4; and R is a hydrogen atom, a hydroxy group or an organic group, and an atom attached to Si is C in a case where R is an organic group.

### INCORPORATION BY REFERENCE

This application is a continuation of PCT Application No. PCT/JP2022/014004, filed on Mar. 24, 2022, which is based upon and claims the benefit of priority from Japanese patent application No. 2021-94354 filed on Jun. 4, 2021, the disclosure of which is incorporated herein in its entirety by reference.

### BACKGROUND

The present invention relates to a novel organosilicon compound, a novel crosslinking agent, a curable composition, a prepreg, a multilayer body, a metal clad laminate and a wiring board.

A wiring board (also referred to as a printed wiring board) is used in applications such as electrical and electronic devices. The wiring board can be manufactured, for example, as follows: A curable composition is impregnated into a fibrous substrate, and the curable composition is (semi-)cured to produce a prepreg. One or more prepregs are sandwiched between a pair of metal foils, and the resulting first temporary multilayer body is heated and pressed to produce a metal clad laminate. The metal foil on the outermost surface of the metal clad laminate is used to form a conductive pattern (also referred to as a circuit pattern) of wiring or the like. The outermost metal foil may be arranged only on one side of the first temporary multilayer body.

One or more prepregs are further stacked on the resulting wiring board, which is sandwiched between a pair of metal foils, and the obtained second temporary multilayer body is heated and pressed to form a conductive pattern of wiring or the like using the metal foil on the outermost surface, thereby manufacturing a multilayer wiring board (also referred to as a multilayer printed wiring board). The outermost metal foil may be arranged only on one side of the second temporary multilayer body.

The heat-pressed product of the prepreg includes a fibrous substrate, a resin and an inorganic filler (also referred to as filler) and is also referred to as a composite substrate. The composite substrate in the wiring board functions as an insulating layer.

The resin contained in the prepreg is a (semi-)cured product of the curable composition, and the resin contained in the composite substrate is a cured product of the curable composition.

In recent applications such as portable electronic devices, signals have become increasingly high-frequency as higher speeds and larger capacities of communication have been achieved. A wiring board used in such applications is required to have a reduced transmission loss in a high-frequency region, which mainly includes a conductor loss caused by the surface resistance of metal foil and a dielectric loss cause by the dielectric dissipation factor (D_{f}) of the composite substrate. For this reason, the resin contained in the composite substrate for the wiring board used in the above applications is required to have reduced dielectric loss in the high-frequency region. The dielectric dissipation factor (D_{f}) generally depends on frequency. Given the same material, the higher the frequency, the larger the dielectric dissipation factor (D_{f}) tends to be. The resin contained in the composite substrate preferably has a low dielectric dissipation factor (D_{f}) under high-frequency condition.

If there is a big difference in coefficient of thermal expansion (CTE) between the prepreg or composite substrate and the metal foil, misalignment or delamination of the metal foil may occur when heating and pressing the first temporary multilayer body containing the prepreg and the metal foil or the second temporary multilayer body containing the composite substrate, the prepreg and the metal foil. Preferably, the difference in the coefficient of thermal expansion (CTE) between the prepreg or composite substrate and the metal foil is small. Since the resin generally has a larger coefficient of thermal expansion (CTE) than the metal foil, a lower coefficient of thermal expansion (CTE) for the prepreg and composite substrate is preferred.

The wiring board may be used in a relatively high-temperature environment. Even in this case, in order to ensure the reliability of the wiring board, the resin contained in the prepreg and the composite substrate preferably has a sufficiently high glass transition temperature (Tg).

In the wiring board, adhesion between the composite substrate and the metal foil is important. Conventionally, there is a technique of roughening the surface of the metal foil on the composite substrate side to improve adhesion between the composite substrate and the metal foil. However, this technique is not preferred because a loss of a high-frequency electrical current easily occurs.

As a technique for enhancing the adhesion between the composite substrate and the metal foil without roughening the surface of the metal foil on the composite substrate side, Japanese Unexamined Patent Application Publication No. 2004-259899 discloses a resin composition for a wiring board containing a polyphenylene oxide-based resin composed of polyphenylene oxide and trialkenyl isocyanurate, and vinylsilanes such as trimethoxyvinylsilane (TMVS) and triethoxyvinylsilane (TEVS), and a wiring board obtained using the resin composition (claims 1 to 4).

Vinylsilanes such as trimethoxyvinylsilane (TMVS) and triethoxyvinylsilane (TEVS) used in Japanese Unexamined Patent Application Publication No. 2004-259899 are silane coupling agents containing a bond between Si and an oxygen atom (O) as a polar atom.

The present inventors have investigated and found that when a silane coupling agent containing a bond between Si and an oxygen atom (O) as a polar atom is added to a curable composition, the resulting composite substrate tends to have an increased dielectric dissipation factor (D_{f}).

The present inventors have found that an organosilicon compound having a specific chemical structure which contains two or more reactive vinyl groups without a bond between Si and a polar atom can be used as a crosslinking agent for a curable composition and that the composite substrate obtained using the curable composition containing the same has an effectively reduced dielectric dissipation factor (D_{f}) under high-frequency conditions, a sufficiently low coefficient of thermal expansion (CTE), a sufficiently high glass transition temperature (Tg), and good properties for use as a wiring board in a high-frequency region.

In Japanese Unexamined Patent Application Publication No. 2004-259899, the silane coupling agent is used to enhance the adhesion between the composite substrate and the metal foil, and there is no description or suggestion for the use of an organosilicon compound as a crosslinking agent.

Other related art of the present invention includes JOURNAL OF POLYMER SCIENCE, PART A: POLYMER CHEMISTRY 2015, 53, 1707-1718, J. Org. Chem. 2013, 78, 3329-3335, and Korean Patent No., KR10-1481417.

In JOURNAL OF POLYMER SCIENCE, PART A: POLYMER CHEMISTRY 2015, 53, 1707-1718, an organosilicon compound is synthesized in which two 4-vinylphenyl groups and two alkyl groups (specifically, —C₈H₁₇) are bonded to Si. The reaction scheme is as follows. In JOURNAL OF POLYMER SCIENCE, PART A: POLYMER CHEMISTRY 2015, 53, 1707-1718, the synthesized organosilicon compound is polymerized, and fluorescent properties of the obtained linear polymer are evaluated. In JOURNAL OF POLYMER SCIENCE, PART A: POLYMER CHEMISTRY 2015, 53, 1707-1718, the organosilicon compound is used as a monomer, and there is no description or suggestion for its use as a crosslinking agent and no description of its dielectric properties.

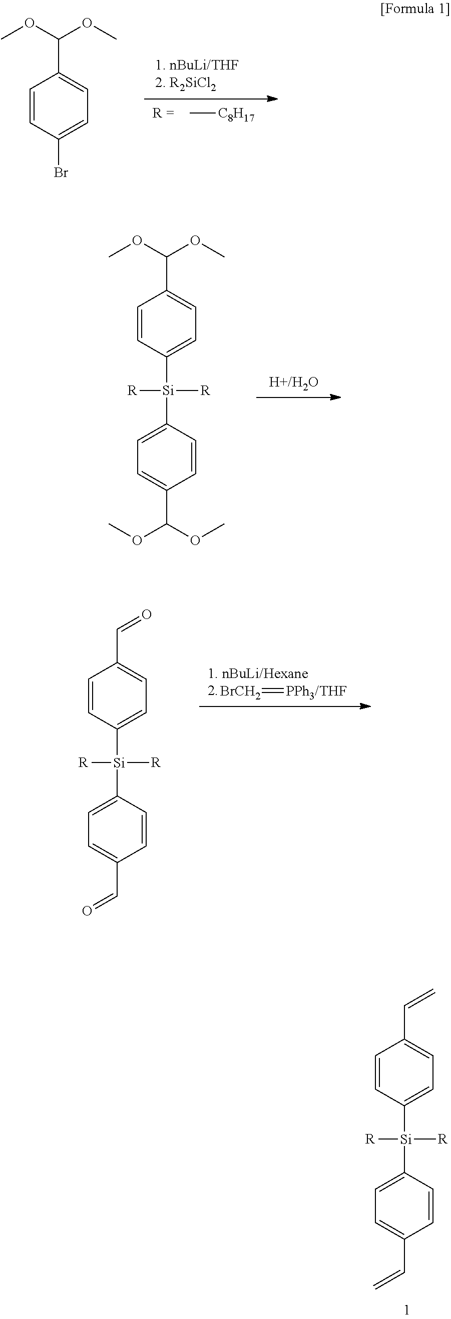

In J. Org. Chem. 2013, 78, 3329-3335, an organosilicon compound is synthesized in which two 2-vinylphenyl groups and two alkyl groups (specifically, -Me, -Et or -Ph) are bonded to Si. In J. Org. Chem. 2013, 78, 3329-3335., the synthesized organosilicon compound is subjected to ring-closing metathesis to synthesize dibenzoheteropins. The reaction scheme is as follows. In J. Org. Chem. 2013, 78, 3329-3335, there is no description for the use of the organosilicon compound, no description or suggestion for its use as a crosslinking agent and no description of its dielectric properties.

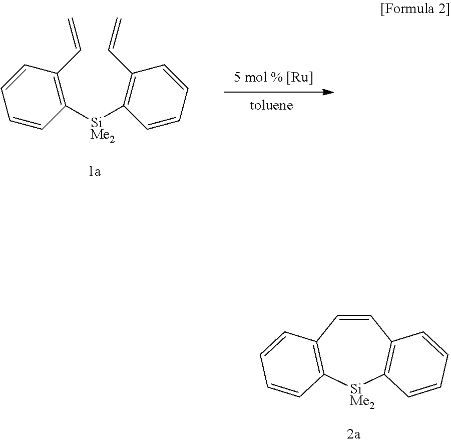

In Korean Patent No., KR10-1481417, a plurality of organosilicon compounds are synthesized in which two 2-, 3- or 4-vinylphenyl groups and two alkyl groups are substituted on Si. Examples of the organosilicon compound synthesized in Korean Patent No., KR10-1481417 are shown in [Formula 3] below. In Korean Patent No., KR10-1481417, the organosilicon compound is used for a gas barrier application, and there is no description or suggestion for its use as a crosslinking agent and no description of its dielectric properties.

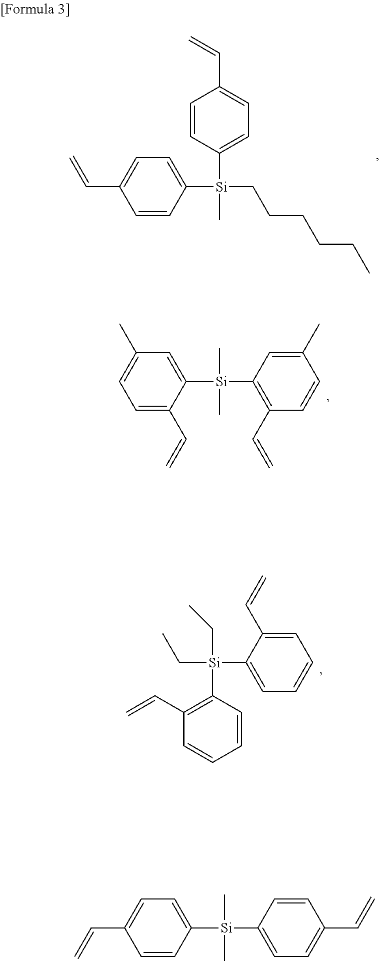

Besides the above, some organosilicon compounds have been reported to have all four atoms attached to Si as nonpolar atoms and two or more reactive vinyl groups. However, in the past, there is no report on the use of an organosilicon compound with all four atoms attached to Si as nonpolar atoms and two or more reactive vinyl groups as a crosslinking agent. All the organosilicon compounds with all four atoms attached to Si as nonpolar atoms and two or more reactive vinyl groups are novel as crosslinking agents.

Furthermore, among the organosilicon compounds with all four atoms attached to Si as nonpolar atoms and two or more reactive vinyl groups, some organosilicon compounds having a specific structure are novel as compounds.

Specifically, polyfunctional organosilicon compounds containing all four atoms attached to Si as nonpolar atoms and three or four reactive functional groups including vinylphenyl groups (a benzene ring in the organosilicon compound is optionally substituted) are novel as compounds.

The present invention has been made in view of the above circumstances, and an object thereof is to provide a novel organosilicon compound suitable for use, for examples, as a crosslinking agent.

Another object of the present invention is to provide a novel crosslinking agent which is suitable for use in a curable composition and capable of producing a (semi-)cured product with effectively reduced dielectric dissipation factor (Df) under high-frequency conditions, sufficiently low coefficient of thermal expansion (CTE) and sufficiently high glass transition temperature (Tg), as well as a curable composition using this agent.

Although the novel organosilicon compound and novel crosslinking agent of the present invention are suitable for use in a curable composition for applications such as a prepreg, a metal clad laminate and a wiring board, they can be used in any application.

### SUMMARY

The present invention provides the following novel organosilicon compound, novel crosslinking agent, curable composition, prepreg, multilayer body, metal clad laminate and wiring board.
[1] An organosilicon compound represented by the following formula (1TQ).
[2] A crosslinking agent represented by the following formula (1TQ):

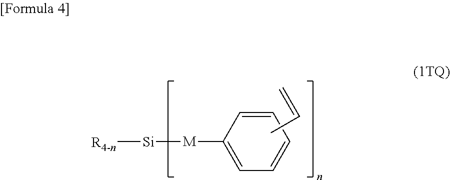

in which M is a single bond or an optionally substituted alkylene group having 1 to 20 carbon atoms; the benzene ring optionally has a substituent; the vinyl group is attached to the benzene ring at any position; n is an integer of 3 or 4; and R is a hydrogen atom, a hydroxy group or an organic group, and an atom attached to Si is C in a case where R is an organic group.
[3] A curable composition including the crosslinking agent according to [2] and a curable compound having two or more crosslinkable functional groups capable of crosslinking with the crosslinking agent.
[4] A prepreg including a fibrous substrate and a semi-cured or cured product of the curable composition according to [3].
[5] A multilayer body including a substrate and a curable composition layer consisting of the curable composition according [3].
[6] A multilayer body including a substrate and a (semi-)cured product-containing layer containing a semi-cured or cured product of the curable composition according [3].
[7] The multilayer body according [5] or [6], in which the substrate is a resin film or metal foil.
[8] A metal clad laminate including an insulating layer containing a cured product of the curable composition according to [3] and metal foil.
[9] A wiring board including an insulating layer containing a cured product of the curable composition according to [3] and wiring.

The present invention can provide a novel organosilicon compound suitable for use, for example, as a crosslinking agent. The present invention can also provide a novel crosslinking agent which is suitable for use in a curable composition and capable of producing a (semi-)cured product with effectively reduced dielectric dissipation factor (D_{f}) under high-frequency conditions, sufficiently low coefficient of thermal expansion (CTE) and sufficiently high glass transition temperature (Tg), as well as a curable composition using this agent.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a schematic cross-sectional view of a metal clad laminate according to a first embodiment of the present invention;

FIG. 2 is a schematic cross-sectional view of a metal clad laminate according to a second embodiment of the present invention; and

FIG. 3 is a schematic cross-sectional view of a wiring board according to an embodiment of the present invention.

### DESCRIPTION OF EMBODIMENTS

As used herein, (semi-)curing is a general term for semi-curing and curing.

As used herein the term “wiring board” includes a multilayer wiring board unless otherwise specified.

As used herein, the term “high-frequency region” is defined as a region with a frequency of 1 GHz or higher.

As used herein, the term “number average molecular weight (Mn)” means the number average molecular weight in terms of polystyrene obtained by a gel permeation chromatography (GPC) method, unless otherwise specified.

As used herein, the term “to” indicating a numerical range is used in a sense that numerical values described before and after “to” are included as a lower limit value and an upper limit value.

Hereinafter, embodiments of the present invention are described.

### Novel Organosilicon Compound and Novel Crosslinking Agent

The organosilicon compound of the present invention is represented by the following formula (1TQ).

The organosilicon compound of the present invention is suitable for use, for example, as a crosslinking agent.

The crosslinking agent of the present invention is represented by the following formula (1TQ):

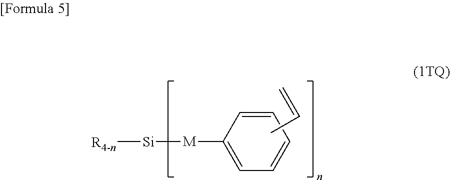

in which M is a single bond or an optionally substituted alkylene group having 1 to 20 carbon atoms; the benzene ring optionally has a substituent; the vinyl group is attached to the benzene ring at any position; n is an integer of 3 or 4; and R is a hydrogen atom, a hydroxy group or an organic group, and an atom attached to Si is C in a case where R is an organic group.

The organosilicon compound and the crosslinking agent of the present invention can be used in any application and are suitable for use in a curable composition, a prepreg, a multilayer body, a metal clad laminate and a wiring board, for example.

### Curable Composition

The curable composition of the present invention includes the crosslinking agent of the present invention and a curable compound having two or more crosslinkable functional groups capable of crosslinking with the crosslinking agent.

The curable composition may be either a thermosetting composition or an active energy ray-curable composition. The active energy ray-curable composition is a composition cured by irradiation with an active energy ray, such as an ultraviolet ray and an electron beam, and is preferably a thermosetting composition for applications such as a metal clad laminate and a wiring board.

Examples of the curable compound include a monomer, an oligomer and prepolymer. One or more of these can be used.

Examples of the cured product of the curable compound include a polyphenylene ether resin (PPE), a bismaleimide resin, an epoxy resin, a fluorine resin, a polyimide resin, an olefin resin, a polyester resin, a polystyrene resin, a hydrocarbon elastomer, a benzoxazine resin, an active ester resin, a cyanate ester resin, a butadiene resin, a hydrogenated or non-hydrogenated styrene-butadiene resin, a vinyl resin, a cycloolefin polymer, an aromatic polymer, a divinyl aromatic polymer, and combinations thereof.

In applications such as a metal clad laminate and a wiring board, the cured product of the curable compound preferably contains a polyphenylene ether resin (PPE).

As used herein, the term “polyphenylene ether resin (PPE)” includes an unmodified polyphenylene ether resin and a modified polyphenylene ether resin, unless otherwise specified.

In the above applications, the curable compound is preferably, for example, a polyphenylene ether oligomer represented by the following formula (P).

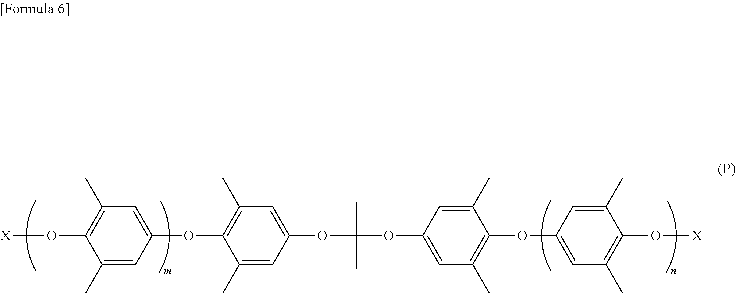

X at both ends of the formula (P) each independently represents a group represented by the following formula (x1) or formula (x2), where “*” represents a bond to an oxygen atom.

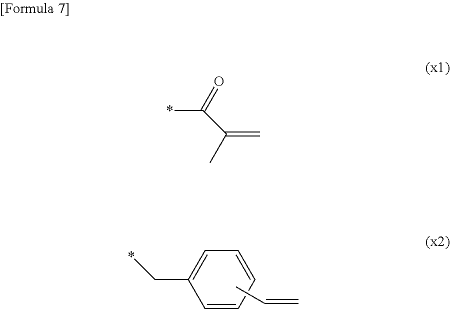

m is preferably 1 to 20, more preferably 3 to 15.

n is preferably 1 to 20, more preferably 3 to 15.

The (semi-)cured product of the curable composition includes a reaction product of the curable compound with the crosslinking agent of the present invention.

The number average molecular weight (Mn) of the oligomer is not particularly limited but is preferably 1,000 to 5,000, and more preferably 1,000 to 4,000.

The curable composition preferably includes one or more polymerization initiators. As the polymerization initiators, organic peroxides, azo-based compounds, other known polymerization initiators and combinations thereof can be used. Specific examples thereof include dicumyl peroxide, benzoyl peroxide, cumene hydroperoxide, 2,5-dimethylhexane-2,5-dihydrogen peroxide, 2,5-dimethyl-2,5-di(t-butylperoxy)hexin-3, di-t-butyl peroxide, t-butylcumyl peroxide, α,α′-di(t-butylperoxy)diisopropylbenzene, 2,5-dimethyl-2,5-di(t-butylperoxy)hexane, di-t-butyl peroxyisophthalate, t-butyl peroxybenzoate, 2,2-bis(t-butylperoxy)butane, 2,2-bis(t-butylperoxy)octane, 2,5-dimethyl-2,5-di(benzoylperoxy)hexane, di(trimethylsilyl)peroxide, trimethylsilyl triphenylsilyl peroxide and azobisisobutyronitrile.

The curable composition can optionally contain one or more additives, such as an inorganic filler (also referred to as a filler), a compatibilizers and a flame retardant, if necessary.

Examples of the inorganic filler include silica such as spherical silica; metal oxides such as alumina, titanium oxide and mica; metal hydroxides such as aluminum hydroxide and magnesium hydroxide; talc; aluminum borate; barium sulfate; and calcium carbonate. One or more of these can be used. Among them, silica, mica, talc and the like

are preferred, and spherical silica is more preferred, from the viewpoint of low thermal expansion.

The inorganic filler may be surface-treated with a silane coupling agent of an epoxy silane type, a vinyl silane type, a methacrylic silane type or an amino silane type. The timing of the surface treatment with the silane coupling agent is not particularly limited. The inorganic filler surface-treated with the silane coupling agent may be prepared in advance, or the silane coupling agent may be added by an integral blend method during the preparation of the curable composition.

Examples of the flame retardant include a halogen flame retardant and a phosphorus flame retardant. One or more of these can be used. Examples of the halogen flame retardant include brominated flame retardants such as pentabromodiphenyl ether, octabromodiphenyl ether, decabromodiphenyl ether, tetrabromobisphenol A and hexabromocyclododecane; and chlorinated flame retardants such as chlorinated paraffin. Examples of the phosphorus flame retardant include phosphate esters such as a fused phosphate ester and a cyclic phosphate ester; phosphazene compounds such as a cyclic phosphazene compound; phosphinate flame retardants such as an aluminum dialkylphosphinate salt; melamine flame retardants such as melamine phosphate and melamine polyphosphate; and phosphine oxide compounds having a diphenylphosphine oxide group.

The curable composition may optionally contain one or more organic solvents, if necessary. Examples of the organic solvents include, but are not particularly limited to, ketones such as methyl ethyl ketone; ethers such as dibutyl ether; esters such as ethyl acetate; amides such as dimethylformamide; aromatic hydrocarbons such as benzene, toluene and xylene; and chlorinated hydrocarbons such as trichloroethylene.

In the curable composition, the solid concentration and formulation composition can be designed according to the application or the like.

For an application such as a prepreg, the solid concentration is preferably 50 to 90% by mass.

### Prepreg

The prepreg of the present invention include a fibrous substrate and a (semi-)cured product of the curable composition of the present invention. The (semi-)cured product may optionally contain an additive such as an inorganic filler (a filler), if necessary.

The prepreg can be produced by impregnating a fibrous substrate with the curable composition and (semi-)curing, for example, by thermal curing.

Examples of the material of the fibrous substrate include, but are not particularly limited to, inorganic fibers such as a glass fiber, a silica fiber and a carbon fiber; organic fibers such as an aramid fiber and a polyester fiber; and combinations thereof. In applications such as a metal clad laminate and a wiring board, the glass fiber or the like is preferred. Examples of forms of the glass fibrous substrate include glass cloth, glass paper and glass mat.

Curing conditions for the curable composition can be set according to the composition of the curable composition, and semi-curing conditions (conditions under which complete curing does not occur) are preferred.

In the case of using a curable composition containing a polyphenylene ether oligomer represented by the above formula (P), thermal curing by heating at, for example, 80 to 180° C. for 1 to 10 minutes is preferred.

In applications such as a metal clad laminate and a wiring board, it is preferable to adjust the composition of the curable composition and curing conditions so that the resin content in the resulting prepreg is in the range of 40 to 80% by mass.

### Multilayer Body

The first multilayer body of the present invention includes a substrate and a curable composition layer consisting of the curable composition of the present invention described above.

The second multilayer body of the present invention includes a substrate and a (semi-)cured product-containing layer containing the (semi-)cured product of the curable composition of the present invention described above.

In the first and second multilayer bodies of the present invention, examples of the substrate include, but are not particularly limited to, a resin film, a metal foil and a combination thereof.

The (semi-)cured product-containing layer may be a layer containing a fibrous substrate and a (semi-)cured product of the curable composition of the present invention.

The resin film is not particularly limited, and a known resin film is available. Examples of constituent resins of the resin film include polyimide, polyethylene terephthalate (PET), polyethylene naphthalate, cycloolefin polymer and polyether sulfide.

Due to its low electrical resistance, the metal foil is preferably copper foil, silver foil, gold foil, aluminum foil and combinations thereof, and more preferably copper foil and the like.

### Metal Clad Laminate

The metal clad laminate of the present invention includes an insulating layer containing a cured product of the curable composition of the present invention and metal foil.

The insulating layer may be a layer containing a fibrous substrate and a cured product of the curable composition of the present invention.

Due to its low electrical resistance, the metal foil is preferably copper foil, silver foil, gold foil, aluminum foil and combinations thereof, and more preferably copper foil and the like. The metal foil may have a metal plating layer on its surface. The metal foil may be a metal foil with a carrier including an ultra-thin metal foil and a carrier metal foil supporting the ultrathin metal foil. The metal foil may have at least one surface subjected to surface treatments such as anticorrosion, silanization, roughening and barrier-forming treatment.

The thickness of the metal foil is not particularly limited but is preferably 0.1 to 100 μm, more preferably 0.2 to 50 μm, and particularly preferably 1.0 to 40 μm since it is suitable for the formation of a conductive pattern (also referred to as a circuit pattern) such as wiring.

The metal clad laminate may be a single-sided metal clad laminate with metal foil on one side or a double-sided metal clad laminate with metal foil on both sides and is preferably a double-sided metal clad laminate.

The single-sided metal clad laminate can be produced by stacking one or more of the above prepregs and metal foil and heating and pressing the resulting first temporary multilayer body.

The double-sided metal clad laminate can be produced by sandwiching one or more of the above prepregs between a pair of metal foils and heating and pressing the resulting first temporary multilayer body.

A metal clad laminate that uses copper foil as the metal foil is referred to as a copper clad laminate (CCL).

The insulating layer preferably consists of a heat-pressed product of the prepreg, which contains a fibrous substrate and a resin and may optionally contain one or more additives such as an inorganic fillers and a flame retardant, if necessary. The heat-pressed product of the prepreg is also referred to as a composite substrate.

The heating and pressing conditions of the first temporary multilayer body are not particularly limited, and for example, a temperature of 170 to 250° C., a pressure of 0.3 MPa to 30 MPa, and a time of 3 to 240 minutes are preferred.

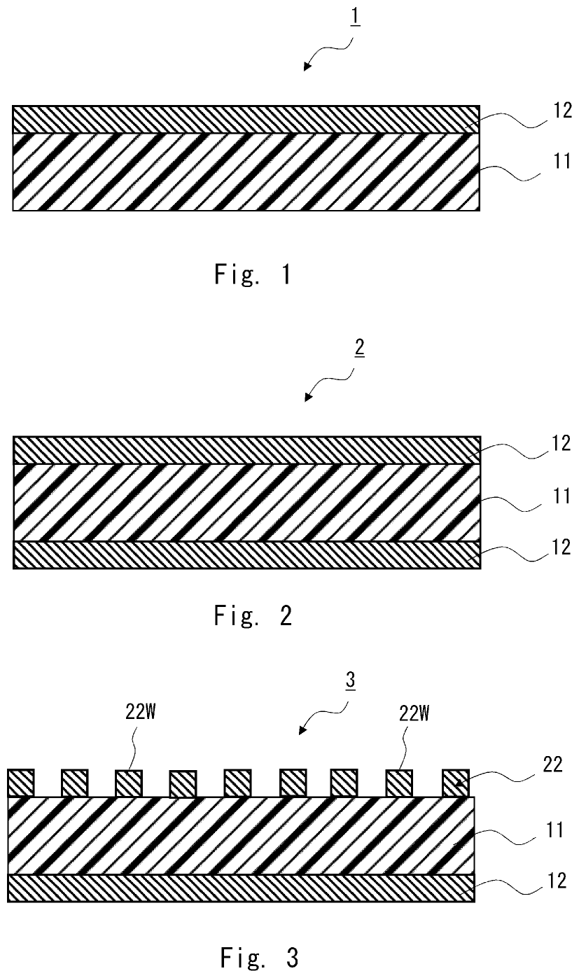

FIGS. 1 and 2 show schematic cross-sectional views of metal clad laminates according to the first and second embodiments of the present invention.

The metal clad laminate 1 shown in FIG. 1 is a single-sided metal clad laminate (multilayer body) in which metal foil (metal layer) 12 is laminated on one side of a composite substrate (cured product-containing layer) 11, which consists of a heat-pressed product of the prepreg and contains a cured product of the curable composition of the present invention.

The metal clad laminate 2 shown in FIG. 2 is a double-sided metal clad laminate in which metal foil (metal layer) 12 is laminated on both sides of a composite substrate (cured product-containing layer) 11, which consists of a heat-pressed product of the prepreg and contains a cured product of the curable composition of the present invention.

The metal clad laminates 1 and 2 may have layers other than those described above.

The metal clad laminates 1 and 2 can have an adhesive layer between the composite substrate (cured product-containing layer) 11 and the metal foil (metal layer) 12 in order to enhance the adhesion therebetween. As the material of the adhesive layer, a known material is available. Examples thereof include an epoxy resin, a cyanate ester resin, an acrylic resin, a polyimide resin, a maleimide resin, an adhesive fluororesin and combinations thereof. Examples of commercially available adhesive fluororesins include “Fluon LM-ETFE LH-8000,” “AH-5000,” “AH-2000” and “EA-2000,” all of which are manufactured by AGC Inc.

The thickness of the composite substrate can be designed as appropriate according to the application. From the viewpoint of preventing disconnection of the wiring board, the thickness is preferably 50 μm or more, more preferably 70 μm or more, and particularly preferably 100 μm or more. From the viewpoint of flexibility, miniaturization, and weight reduction of the wiring board, the thickness is preferably 300 μm or less, more preferably 250 μm or less, and particularly preferably 200 μm or less.

### Wiring Board

The wiring board of the present invention includes an insulating layer containing a cured product of the curable composition of the present invention and wiring.

The wiring board can be manufactured by forming a conductive pattern (circuit pattern) such as wiring using the metal foil on the outermost surface of the metal clad laminate of the present invention described above. Examples of methods of forming a conductive pattern such as wiring include a subtractive method, in which metal foil is etched to form wiring or the like, and modified semi additive process (MSAP), in which metal foil is plated to form wiring on the metal foil.

FIG. 3 shows a schematic cross-sectional view of a wiring board according to an embodiment of the present invention. In the wiring board 3 shown in FIG. 3, a conductive pattern (circuit pattern) 22 such as wiring 22W is formed by using the metal foil 12 on at least one outermost surface of the metal clad laminate 2 of the second embodiment shown in FIG. 2.

The wiring board 3 is composed of a heat-pressed product of the prepreg, in which the conductive pattern (circuit pattern) 22 such as wiring 22W is formed on at least one surface of the composite substrate (cured product-containing layer, insulating layer) 11 containing a cured product of the curable composition of the present invention.

One or more prepregs may be further stacked on the resulting wiring board, which is sandwiched between a pair of metal foils, and the obtained second temporary multilayer body may be heated and pressed to form a conductive pattern of wiring or the like using the outermost metal foil, thereby manufacturing a multilayer wiring board (also referred to as a multilayer printed wiring board). The outermost metal foil may be arranged only on one side of the second temporary multilayer body.

The wiring board of the present invention is suitable for use in a high-frequency region (a region with a frequency of 1 GHz or higher).

In recent applications such as portable electronic devices, signals have become increasingly high-frequency as higher speeds and larger capacities of communication have been achieved. The wiring board used in the such applications is required to have reduced transmission loss in the high-frequency region. For this reason, the resin contained in the composite substrate for the wiring board used in the above applications is required to have reduced dielectric loss in the high-frequency region. The dielectric dissipation factor (D_{f}) generally depends on frequency. Given the same material, the higher the frequency, the larger the dielectric dissipation factor (D_{f}) tends to be. The resin contained in the composite substrate preferably has a low dielectric dissipation factor (D_{f}) under high-frequency condition.

If there is a big difference in coefficient of thermal expansion (CTE) between the prepreg or composite substrate and the metal foil, misalignment or delamination of the metal foil may occur in the case of heating and pressing the first temporary multilayer body containing the prepreg and the metal foil or the second temporary multilayer body containing the composite substrate, the prepreg and the metal foil. Preferably, the difference in the coefficient of thermal expansion (CTE) between the prepreg or composite substrate and the metal foil is small. Since the resin generally has a larger coefficient of thermal expansion (CTE) than the metal foil, a lower coefficient of thermal expansion (CTE) for the prepreg and composite substrate is preferred.

The wiring board may be used in a relatively high-temperature environment. Even in this case, in order to ensure the reliability of the wiring board, the resin contained in the prepreg and the composite substrate preferably has a sufficiently high glass transition temperature (Tg).

In the organosilicon compound and crosslinking agent of the present invention, unlike the silane coupling agent used in Japanese Unexamined Patent Application Publication No. 2004-259899 listed in the Background Art section, all four atoms attached to Si are nonpolar atoms (specifically, hydrogen atoms or carbon atoms).

The present inventors have investigated and found that when the organosilicon compound of the present invention is added to the curable composition, the organosilicon compound functions as a crosslinking agent for crosslinking the curable compound having two or more crosslinking functional groups and can effectively reduce the dielectric dissipation factor (D_{f}) of the (semi-)cured product of the curable composition.

It was also found that the (semi-)cured product of the curable composition containing the organosilicon compound of the present invention had a sufficiently low coefficient of thermal expansion (CTE) and a sufficiently high glass transition temperature (Tg).

In addition, it was found that the (semi-)cured product of the curable composition containing the organosilicon compound of the present invention also had a practically good adhesion to metals such as copper foil.

By adding the organosilicon compound of the present invention as a crosslinking agent to the curable composition, it is possible to produce a (semi-)cured product with effectively reduced dielectric dissipation factor (D_{f}) under high-frequency conditions, sufficiently low coefficient of thermal expansion (CTE) and sufficiently high glass transition temperature (Tg). This (semi-)cured product is suitable for a composite substrate, an insulating layers and the like, which are suitable for wiring boards used in the high-frequency region.

The dielectric dissipation factor (D_{f}) of the (semi-)cured product of the curable composition of the present invention and the composite substrate containing the same under high-frequency conditions is preferably within, for example, the following ranges.

The dielectric dissipation factor (D_{f}) at a frequency of 10 GHz is preferably smaller, preferably 0.01 or less, more preferably 0.005 or less, and particularly preferably 0.003 or less. The lower limit thereof is not particularly limited, for example, 0.0001.

The coefficient of thermal expansion (CTE) of the (semi-)cured product of the curable composition of the present invention and the composite substrate containing the same is preferably within, for example, the following ranges.

The coefficient of thermal expansion (CTE) is preferably smaller, preferably 70 ppm/° C. or less, and more preferably 60 ppm/° C. or less. The lower limit thereof is not particularly limited, for example, 1 ppm/° C.

The glass transition temperature (Tg) of the (semi-)cured product of the curable composition of the present invention is preferably 150° C. or higher, more preferably 180° C. or higher, and particularly preferably 200° C. or higher. The upper limit is not particularly limited, for example, 300° C.

The dielectric dissipation factor (D_{f}), coefficient of thermal expansion (CTE) and glass transition temperature (Tg) can be measured by methods described in the Examples section below.

In the organosilicon compound of the present invention represented by the formula (1TQ), the benzene ring optionally has a substituent. Examples of the substituent that may be contained in the benzene ring include an alkyl group having 1 to 18 carbon atoms and an aryl group. From the viewpoint of availability of raw materials, preferred are a methyl group, an ethyl group, a propyl group, a butyl group, a hexyl group, an octyl group, a phenyl group and a tolyl group. The benzene ring preferably has no substituents.

In the organosilicon compound of the present invention represented by the formula (1TQ), the vinyl group may be attached to the benzene ring at any of ortho-, meta- and para-positions, and can be at ortho- or para-position, and can be at para-position from the viewpoint of smaller steric hindrance during crosslinking reaction and ease of raw material availability and synthesis.

In the organosilicon compound of the present invention represented by the formula (1TQ), the number of reactive functional groups (also simply referred to as the number of functional groups) n is 3 or 4.

It is believed that the greater the number of functional groups n, the higher the crosslinking density of the curable composition and the greater the curing rate.

The present inventors have investigated and found that the dielectric dissipation factor (D_{f}) of the (semi-)cured product of the curable composition can be more effectively reduced when the number of functional groups n is 3 or 4 than when the number of functional groups n is 2.

If the number of functional groups n is large, the curing rate may be too high, leaving unreacted reactive functional groups in the curable composition. The number of functional groups n is more preferably 3 from the viewpoint that the crosslinking reaction of the curable composition can be efficiently proceeded before curing, and an increase in dielectric dissipation factor (D_{f}) due to an unreacted reactive functional group remaining after curing of the curable composition can be suppressed.

Note that the reason why the dielectric dissipation factor (D_{f}) of the (semi-)cured product of the curable composition under high-frequency conditions can be more effectively reduced when the number of functional groups n is 3 or 4, preferably 3, is not always clear, and the above explanation includes the speculation of the present inventors.

In the organosilicon compound of the present invention represented by the formula (1TQ), R is a hydrogen atom, a hydroxy group or an organic group, preferably an optionally substituted alkyl group having 1 to 18 carbon atoms. R preferably does not contain polar atoms such as an oxygen atom (O) since the dielectric dissipation factor (D_{f}) of the (semi-)cured product of the curable composition under high-frequency conditions can be more effectively reduced. R is preferably an alkyl group having 1 to 18 carbon atoms without substituents, more preferably a linear alkyl group having 1 to 18 carbon atoms.

Preferably, R has a larger number of carbon atoms since the polarity of the crosslinked structure decreases, thus more effectively reducing the dielectric dissipation factor (D_{f}) of the (semi-)cured product of the curable composition under high-frequency conditions. For ease of synthesis, the upper limit on the number of carbon atoms is 18. The number of carbon atoms in R is more preferably 3 to 18, and particularly preferably 8 to 18, from the viewpoint of the effect of reducing the dielectric dissipation factor (D_{f}) under high-frequency conditions and the ease of synthesis of the (semi-)cured product of the curable composition.

In the organosilicon compound of the present invention represented by the formula (1TQ), M is a single bond or an optionally substituted alkylene group having 1 to 20 carbon atoms. For ease of synthesis, the upper limit on the number of carbon atoms is 20. From the viewpoint of ease of synthesis of the organosilicon compound, M is preferably a single bond or an alkylene group having 1 to 4 carbon atoms, and more preferably a single bond or a methylene group.

The organosilicon compound of the present invention, represented by the formula (1TQ), can be synthesized by a known synthesis method; for specific synthesis examples, see the Examples section below.

As described above, the present invention can provide a novel organosilicon compound suitable for use, for example, as a crosslinking agent. The present invention can also provide a novel crosslinking agent which is suitable for use in a curable composition and capable of producing a (semi-)cured product with effectively reduced dielectric dissipation factor (D_{f}) under high-frequency conditions, sufficiently low coefficient of thermal expansion (CTE) and sufficiently high glass transition temperature (Tg), as well as a curable composition using this agent.

Although the novel organosilicon compound and novel crosslinking agent of the present invention are suitable for use in a curable composition for applications such as a prepreg, a metal clad laminate and a wiring board, they can be used in any application.

### Application

The novel organosilicon compound of the present invention is suitable for use, for example, as a crosslinking agent.

The crosslinking agent of the present invention is suitable for use in a curable composition containing a curable compound such as a monomer, an oligomer and a prepolymer.

The novel organosilicon compound and novel crosslinking agent of the present invention are suitable for use in a curable composition for applications such as a prepreg, a metal clad laminate and a wiring board.

The curable composition containing the crosslinking agent of the present invention is suitable for use in a curable composition for applications such as a prepreg, a metal clad laminate and a wiring board.

The metal clad laminate of the present invention is suitable for use as a wiring board, for example, for various electrical and electronic devices.

The wiring board of the present invention is suitable for use, for example, in portable electronic devices such as a mobile phone, a smartphone, a personal digital assistant and a laptop computer; antennas for a mobile phone base station and a vehicle; electronic devices such as a server, a router and a backplane; wireless infrastructures; radars for collision avoidance and the like; and various sensors (e.g., automotive sensors such as engine management sensors).

The wiring board of the present invention is particularly suitable for applications in which communication is performed using a high-frequency signal and various applications in which a reduction in transmission loss is required in a high-frequency region.

Hereinafter, the present invention is described in detail with reference to examples, but the present invention is not limited thereto. Examples 1 to 6 and 101 are Examples, while Examples 21, 31 and 32 are Comparative Examples. Unless otherwise specified, room temperature is around 25° C.

### Commercially Available Reagent

In the Examples section, commercially available catalysts and reagents were used as received for reactions unless otherwise specified. The solvents used were dehydrated and deoxygenated commercial solvents.

### Evaluation Item and Evaluation Method of Organosilicon Compound

### (Structure)

The structure of the synthesized organosilicon compound was identified using a nuclear magnetic resonance device (“JNM-AL300” manufactured by JEOL Ltd.) by carrying out ¹H-NMR measurements.

### (Molecular Weight)

The molecular weight of the synthesized organosilicon compound was determined by electron impact (EI) using a gas chromatography-mass spectrometer (GC-HRMS) (“7890A” manufactured by Agilent Technologies/“JMS-T200 AccuTOF GCx-plus” manufactured by JEOL).

### Method of Preparing Sample for Evaluation (Cured Film Product)

The following two polyphenylene ether oligomers were prepared as curable compounds:
(SA9000) bifunctional methacrylic modified PPE (“SA9000” manufactured by SABIC); and
(OPE-2st) bifunctional chloromethylstyrene-modified PPE (“OPE-2st” manufactured by MITSUBISHI GAS CHEMICAL COMPANY, INC.).

SA9000 and OPE-2st are represented by the following formulas.

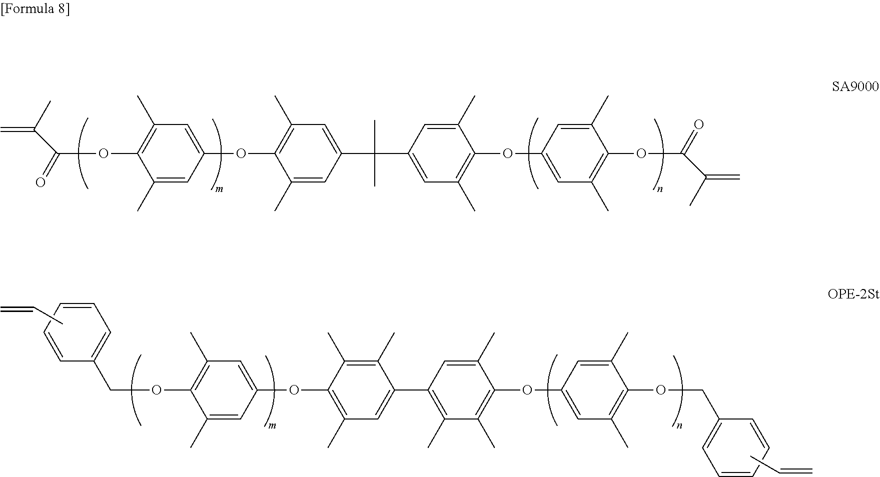

The bifunctional methacrylic modified PPE (SA9000) or bifunctional chloromethylstyrene-modified PPE (OPE-2st), the organosilicon compound synthesized or prepared in each Examples, dicumyl peroxide as a radical polymerization initiator and toluene were mixed in a mass ratio of 7:3:0.1:7 and stirred at room temperature to prepare a toluene solution (curable composition).

Next, the toluene solution was applied onto a polyimide film with a thickness of 125 μm using an applicator (manufactured by YOSHIMITSU SEIKI) to form a 250 μm-thick coating film.

After heat-drying in an oven at 80° C. for 30 minutes in an air atmosphere, the coating film was heated under a nitrogen atmosphere at 200° C. for two hours to cause thermal curing (thermal crosslinking reaction) of the coating film, thus obtaining an evaluation sample (cured film product) having a thickness of about 100 μm. The resulting evaluation sample was subjected to the following evaluations.

### Evaluation Item and Evaluation Method of Cured Film Product

(Dielectric Constant (Dₖ) and Dielectric Dissipation Factor (D_{f}))

Dielectric constant (Dₖ) and dielectric dissipation factor (D_{f}) at 10 GHz of the evaluation sample (cured film product) were measured by the SPDR method using a vector network analyzer (“E8361C” manufactured by Agilent Technologies) at room temperature.

### (Glass Transition Temperature (Tg))

Dynamic viscoelasticity measurement (DMA) was taken on the evaluation sample (cured film product) using a dynamic viscoelasticity measuring device (“DVA 200” manufactured by IT Keisoku Seigyo Co., Ltd.) to measure the glass transition temperature (Tg) (° C.) under conditions of a frequency of 10 Hz, a heating rate of 2° C./min, and a temperature range of 25° C. to 300° C.

### (Coefficient of Thermal Expansion (CTE))

The coefficient of thermal expansion (CTE) of the evaluation sample (cured film product) below the glass transition temperature (Tg) was measured using a thermomechanical analyzer (“TMA/SS7100” manufactured by Hitachi High-Tech Science Corporation, formerly known as SII NanoTechnology Inc.) under conditions of a heating rate of 5° C./min and a temperature range of −50 to 340° C.

### EXAMPLE 1

### Synthesis of Methyltris(4-vinylphenyl)silane (C1-T-p-St-Si)

### Synthesis of Tris(4-formylphenyl)methylsilane

Under a nitrogen atmosphere, a 500 mL four-necked flask was charged with 4-bromobenzaldehyde dimethyl acetal (24.0 g, 102 mmol) and tetrahydrofuran (300 mL). The solution was cooled to −70° C. or lower, and an n-BuLi/n-hexane solution (2.6 mol/L, 39 mL, 100 mmol) was added dropwise thereto over an hour. The reaction solution was then stirred at −70° C. or lower for two hours. To the resulting suspension was added dropwise trichloro(methyl)silane (3.17 mL, 27.1 mmol) over 40 minutes, and the mixture was then stirred at the same temperature as above for two hours. The flask was warmed to room temperature, and the mixture was then stirred for 12 hours. The reaction mixture was quenched with hydrochloric acid (2 mol/L, 120 mL), and diethyl ether (100 mL) was added thereto, followed by extraction to separate an organic phase. Diethyl ether (100 mL) was further added to the water phase, followed by extraction to separate the organic phase. The organic phases obtained from these extractions were combined. The combined organic phases were washed with saturated brine (100 mL), dried over magnesium sulfate and filtered. The filtrate was concentrated in vacuo to give a crude mixture of acetal/aldehyde. To the crude mixture were added tetrahydrofuran (100 mL) and hydrochloric acid (2 mol/L, 100 mL). The mixture was then heated under reflux for two hours and cooled to room temperature. Thereafter, saturated aqueous sodium hydrogen carbonate solution (400 mL) was added dropwise to the reaction solution. Diethyl ether (100 mL) was added to the reaction solution, and extraction was performed three times to separate the organic phase. The organic phases obtained from these extractions were combined. The combined organic phases were washed with saturated brine (100 mL), dried over magnesium sulfate and filtered. The filtrate was concentrated in vacuo to give a crude product (yellow oil). The crude product was purified by silica gel column chromatography (mobile phase: ethyl acetate/n-hexane=1:4 (v/v)) to give 9.95 g of tris(4-formylphenyl)methylsilane as a colorless liquid (yield: 98%, purity: 96%).

The reaction scheme and results of NMR analysis are as follows:

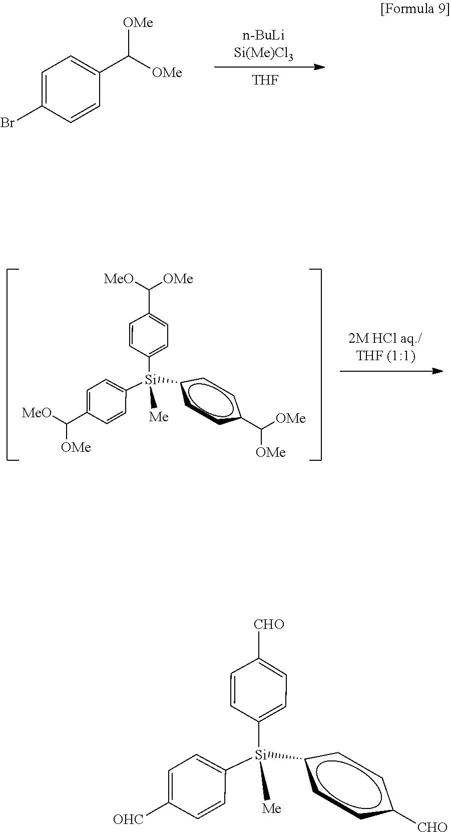

¹H-NMR (CDCl₃): δ (ppm) 10.06 (s, 3H, CHO), 7.89 (d, 6H, J=7.68 Hz, Ar—H), 7.67 (d, 6H, J=7.68 Hz, Ar—H), 0.97 (s, 3H, Si—CH₃).

### Synthesis of Methyltris(4-vinylphenyl)silane

A 500 mL four-necked flask was charged with methyltriphenylphosphonium bromide (27.5 g, 77.0 mmol) and tetrahydrofuran (128 mL) under a nitrogen atmosphere. The flask was cooled to 0° C., and potassium tert-butoxide (9.74 g, 86.8 mmol) was then added to the suspension. The reaction mixture was stirred at the same temperature as above for five minutes or more. To the reaction mixture was added dropwise a solution of tris(4-formylphenyl)methylsilane (8.00 g, 21.4 mmol) in tetrahydrofuran (128 mL) over 20 minutes. The flask was warmed to room temperature, and the mixture was then stirred for two hours. 4-tert-Butylpyrocatechol (0.60 mg) was added to the reaction mixture and then concentrated under reduced pressure at 30° C. Water (200 mL) and diethyl ether (200 mL) were added to the resulting mixture, followed by extraction to separate an organic phase. Diethyl ether (200 mL) was further added to the water phase, followed by extraction to separate the organic phase. The organic phases obtained from these extractions were combined. The combined organic phases were dried over magnesium sulfate and filtered. The filtrate was concentrated under reduced pressure to give a crude mixture. To the crude mixture were added n-hexane (160 mL) and diethyl ether (40 mL), and the mixture was then stirred for 30 minutes. The mixture was filtered through filter paper, and the filtrate was concentrated under reduced pressure to give a crude product (yellow oil). The crude product was purified by silica gel column chromatography (mobile phase: n-hexane) to give 6.41 g of methyltris(4-vinylphenyl)silane (C1-T-p-St-Si) as a colorless liquid (yield: 85%).

The reaction scheme and results of NMR analysis and HRMS analysis are as follows:

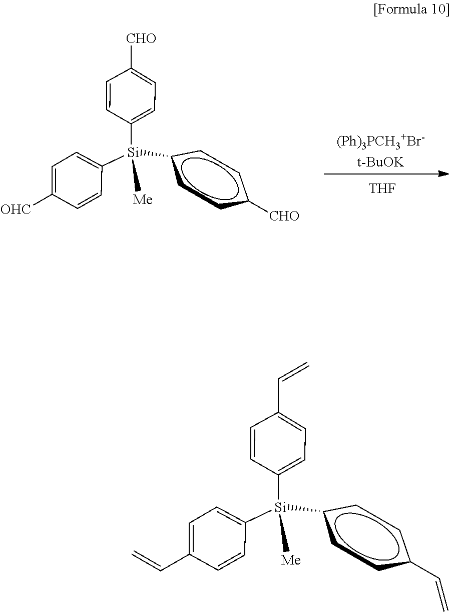

¹H-NMR (CDCl₃): δ (ppm) 7.47 (d, 6H, J=7.68 Hz, Ar—H), 7.39 (d, 6H, J=7.68 Hz, Ar—H), 6.72 (dd, 3H, J=11.1, 17.9 Hz, —CH═CH₂), 5.78 (d, 3H, J=17.9 Hz, —CH═CH₂), 5.27 (d, 3H, J=11.1 Hz, —CH═CH₂), 0.81 (s, 3H, Si—CH₃).

HRMS (EI): m/z Calcd for C₂₅H₂₄Si: (M⁺) 352.165, found 352.162.

### EXAMPLE 2

### Synthesis of Dodecyltris(4-vinylphenyl)silane (C12-T-p-St-Si)

### Synthesis of Dodecyltris(4-formylphenyl)silane

A 500 mL four-necked flask was charged with 4-bromobenzaldehyde dimethyl acetal (24.0 g, 102 mmol) and tetrahydrofuran (300 mL) under a nitrogen atmosphere. The solution was cooled to −66° C. or lower, and an n-BuLi/n-hexane solution (2.6 mol/L, 39 mL, 100 mmol) was added dropwise thereto over an hour. The reaction solution was then stirred at −70° C. or lower for two hours. To the resulting reaction solution was added dropwise dodecyltrichlorosilane (8.08 mL, 27.2 mmol) over 40 minutes, and the mixture was then stirred at the same temperature as above for two hours. The flask was warmed to room temperature, and the mixture was then stirred for 12 hours. The reaction mixture was quenched with hydrochloric acid (2 mol/L, 120 mL), and diethyl ether (100 mL) was added thereto, followed by extraction to separate an organic phase. Diethyl ether (100 mL) was further added to the water phase, followed by extraction to separate the organic phase. The organic phases obtained from these extractions were combined. The combined organic phases were washed with saturated brine (100 mL), dried over magnesium sulfate and filtered. The filtrate was concentrated under reduced pressure to give a crude product. The crude product was purified by silica gel column chromatography (mobile phase: chloroform/n-hexane=1:1 (v/v)) to give 9.53 g of dodecyltris(4-formylphenyl)silane as a colorless liquid (yield: 68%).

The reaction scheme and results of NMR analysis are as follows:

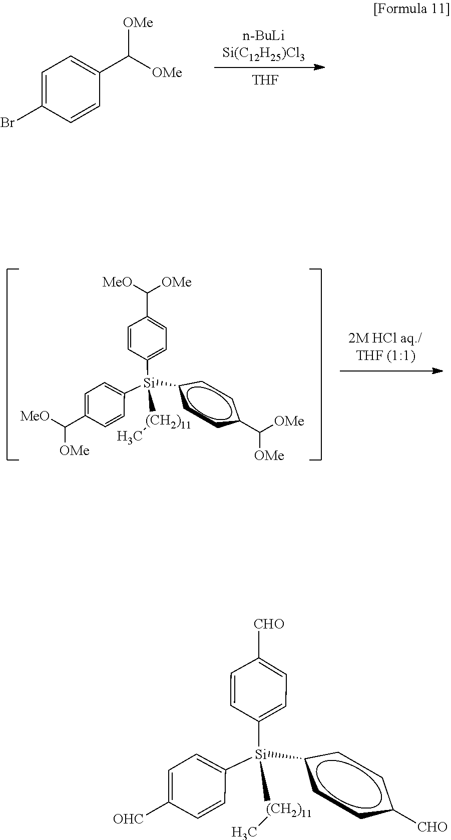

¹H-NMR (CDCl₃): δ (ppm) 10.06 (s, 3H, CHO), 7.89 (d, 6H, J=8.54 Hz, Ar—H), 7.67 (d, 6H, J=8.54 Hz, Ar—H), 1.47-1.39 (m, 6H, —CH₂—), 1.23 (brs, 16H, —CH₂—), 0.87 (t, 3H, J=6.83 Hz, Si—CH₃).

### Synthesis of Dodecyltris(4-vinylphenyl)silane

A 500 mL four-necked flask was charged with methyltriphenylphosphonium bromide (21.3 g, 59.6 mmol) and tetrahydrofuran (136 mL) under a nitrogen atmosphere. The flask was cooled to 0° C., and potassium tert-butoxide (7.53 g, 67.1 mmol) was then added to the suspension. The reaction mixture was stirred at the same temperature as above for five minutes or more. To the reaction mixture was added dropwise a solution of dodecyltris(4-formylphenyl)silane (8.50 g, 16.6 mmol) in tetrahydrofuran (136 mL) over 20 minutes. The flask was warmed to room temperature, and the mixture was then stirred for an hour. 4-tert-Butylpyrocatechol (2.55 mg) was added to the reaction mixture and then concentrated under reduced pressure at 30° C. Water (200 mL) and diethyl ether (200 mL) were added to the resulting mixture, followed by extraction to separate an organic phase. Diethyl ether (200 mL) was further added to the water phase, followed by extraction to separate the organic phase. The organic phases obtained from these extractions were combined. The combined organic phases were dried over magnesium sulfate and filtered. The filtrate was concentrated under reduced pressure to give a crude mixture. To the crude mixture were added n-hexane (160 mL) and diethyl ether (40 mL), and the mixture was then stirred for 30 minutes. The mixture was filtered through filter paper, and the filtrate was concentrated under reduced pressure to give a crude product (yellow oil). The crude product was purified by silica gel column chromatography (mobile phase: n-hexane) to give 4.73 g of dodecyltris(4-vinylphenyl)silane (C12-T-p-St-Si) as a pale yellow liquid (yield: 56%).

The reaction scheme and results of NMR analysis and HRMS analysis are as follows:

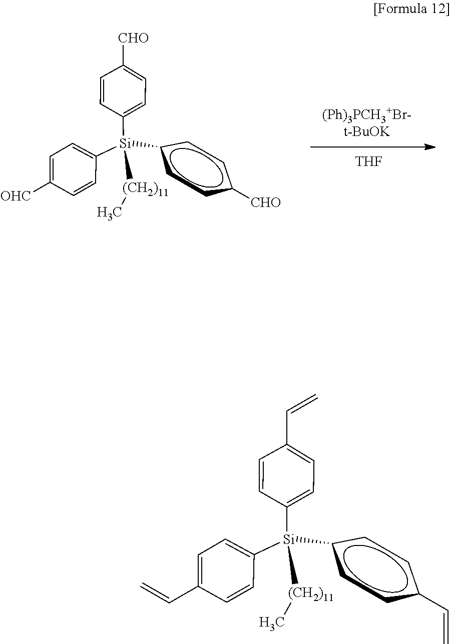

¹H-NMR (CDCl₃): δ (ppm) 7.47 (d, 6H, J=7.68 Hz, Ar—H), 7.39 (d, 6H, J=8.54 Hz, Ar—H), 6.72 (dd, 3H, J=10.7, 17.5 Hz, —CH═CH₂), 5.79 (d, 3H, J=17.9 Hz, —CH═CH₂), 5.27 (d, 3H, J=11.1 Hz, —CH═CH₂), 1.49-1.22 (m, 22H, —CH₂—), 0.86 (t, 3H, J=6.40 Hz, CH₃).

HRMS (EI): m/z Calcd for C₃₆H₄₆Si: (M⁺) 506.337, found 506.331.

### EXAMPLE 3

### Synthesis of Dodecyltris(3-vinylphenyl)silane (C12-T-m-St-Si)

### Synthesis of Dodecyltris(3-formylphenyl)silane

A 500 mL four-necked flask was charged with 3-bromobenzaldehyde diethyl acetal (24.0 g, 90.8 mmol) and tetrahydrofuran (300 mL) under a nitrogen atmosphere. The solution was cooled to −65° C. or lower, and an n-BuLi/n-hexane solution (2.6 mol/L, 35 mL, 91 mmol) was added dropwise thereto over an hour. The reaction solution was then stirred at −70° C. or lower for two hours. To the resulting reaction solution was added dropwise dodecyltrichlorosilane (7.20 mL, 24.2 mmol) over 40 minutes, and the mixture was then stirred at the same temperature as above for two hours. The flask was warmed to room temperature, and the mixture was then stirred for 12 hours. The reaction mixture was quenched with hydrochloric acid (2 mol/L, 120 mL) and stirred at room temperature for an hour to separate an organic phase. Ethyl acetate (100 mL) was further added to the water phase, and extraction was performed twice to separate the organic phase. The organic phases obtained from these extractions were combined. The combined organic phases were washed with saturated brine (100 mL), dried over magnesium sulfate and filtered. The filtrate was concentrated under reduced pressure to give a crude product. The crude product was purified by silica gel column chromatography (mobile phase: chloroform/n-hexane=1:1 (v/v)) to give 10.5 g of dodecyltris(3-formylphenyl)silane as a colorless liquid (yield: 85%).

The reaction scheme and results of NMR analysis are as follows:

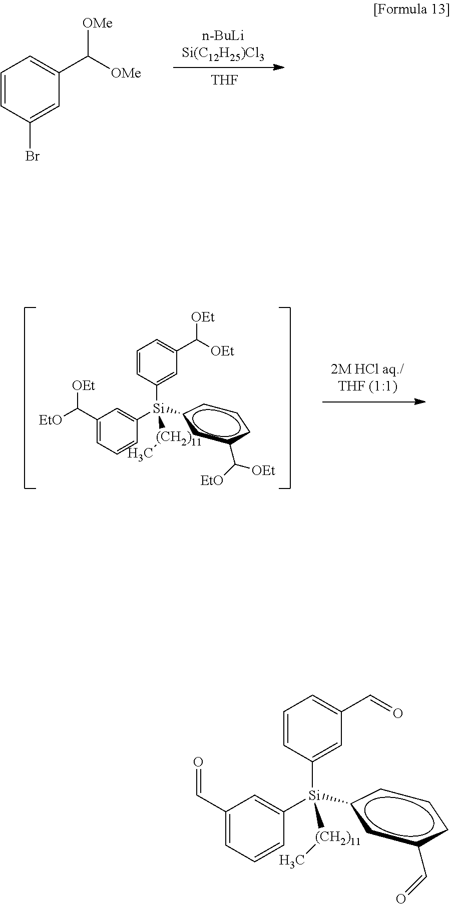

¹H-NMR (CDCl₃): δ (ppm) 10.01 (s, 3H, CHO), 8.00 (brs, 3H, s, Ar—H), 7.97 (td, 3H, J=7.68, 1.71 Hz, Ar—H), 7.76 (d, 3H, J=7.68 Hz, Ar—H), 7.58 (t, 3H, J=7.68 Hz, Ar—H), 1.56-1.33 (m, 6H, —CH₂—), 1.22 (brs, 16H, —CH₂—), 0.87 (t, 3H, J=6.83 Hz, CH₃).

### Synthesis of Dodecyltris(3-vinylphenyl)silane

A 500 mL four-necked flask was charged with methyltriphenylphosphonium bromide (22.6 g, 63.3 mmol) and tetrahydrofuran (144 mL) under a nitrogen atmosphere. The flask was cooled to 0° C., and potassium tert-butoxide (7.98 g, 71.1 mmol) was then added to the suspension. The reaction mixture was stirred at the same temperature as above for five minutes or more. To the reaction mixture was added dropwise a solution of dodecyltris(3-formylphenyl)silane (9.00 g, 17.6 mmol) in tetrahydrofuran (144 mL) over 20 minutes. The flask was warmed to room temperature, and the mixture was then stirred for an hour. 4-tert-Butylpyrocatechol (2.55 mg) was added to the reaction mixture and then concentrated under reduced pressure at 30° C. Water (200 mL) and diethyl ether (200 mL) were added to the resulting mixture, followed by extraction to separate an organic phase. Diethyl ether (200 mL) was further added to the water phase, followed by extraction to separate the organic phase. The organic phases obtained from these extractions were combined. The combined organic phases were dried over magnesium sulfate and filtered. The filtrate was concentrated under reduced pressure to give a crude mixture. To the crude mixture were added n-hexane (160 mL) and diethyl ether (40 mL), and the mixture was then stirred for 30 minutes. The mixture was filtered through filter paper, and the filtrate was concentrated under reduced pressure to give a crude product (red oil). The crude product was purified by silica gel column chromatography (mobile phase: n-hexane) to give 6.32 g of dodecyltris(3-vinylphenyl)silane (C12-T-m-St-Si) as a pale yellow liquid (yield: 71%).

The reaction scheme and results of NMR analysis and HRMS analysis are as follows:

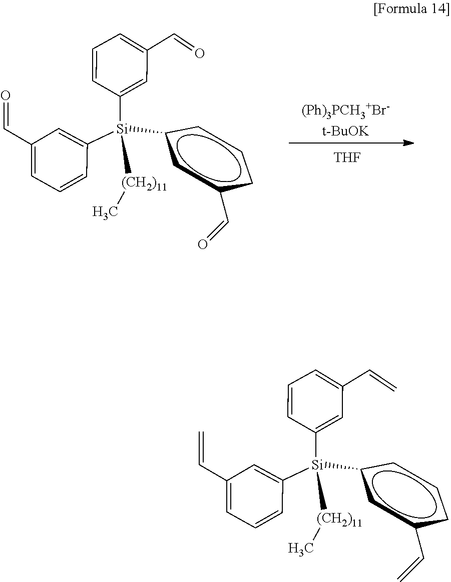

¹H-NMR (CDCl₃): δ (ppm) 7.54 (brs, 3H, Ar—H), 7.48 (d, 3H, J=6.83 Hz, Ar—H), 7.40 (d, 3H, J=6.83 Hz, Ar—H), 7.32 (t, 3H, J=6.83 Hz, Ar—H), 6.69 (dd, 3H, J=11.10, 17.93 Hz, —CH═CH₂), 5.69 (d, 3H, J=17.93 Hz, —CH═CH₂), 5.21 (d, 3H, J=11.10 Hz, —CH═CH₂), 1.52-1.42 (m, 2H, —CH₂—), 1.42-1.32 (m, 4H, —CH₂—), 1.32-1.11 (m, 16H, —CH₂—), 0.87 (t, 3H, J=6.83 Hz, CH₃).

HRMS (EI): m/z Calcd for C₃₆H₄₆Si: (M⁺) 506.337, found 506.329.

### EXAMPLE 4

### Synthesis of Dodecyltris(4-vinylbenzyl)silane (C12-T-p-Bn-Si)

A 50 mL four-necked flask was charged with magnesium (turning, 0.898 g, 36.9 mmol) and diethyl ether (21.1 mL) under a nitrogen atmosphere, and the mixture was cooled in an ice bath. To the suspension was added dropwise a solution of 4-(chloromethyl)styrene (5.12 g, 33.5 mmol) in diethyl ether (10.5 mL) over an hour. After the mixture was stirred at the same temperature as above for an hour, dodecyltrichlorosilane (3.33 mL, 11.2 mmol) was added dropwise thereto over 20 minutes. The flask was warmed to room temperature, and the mixture was then stirred for 12 hours. Water (15 mL) was added to the reaction solution, and the mixture was stirred for 10 minutes or more to separate an organic phase. Diethyl ether (30 mL) was further added to the water phase, and extraction was performed twice to separate the organic phase. The organic phases obtained from these extractions were combined. The combined organic phases were dried over magnesium sulfate and filtered. The filtrate was concentrated under reduced pressure to give a crude product. The crude product was purified by silica gel column chromatography (mobile phase: n-hexane) to give 1.09 g of dodecyltris(4-vinylbenzyl)silane (C12-T-p-Bn-Si) as a pale yellow liquid (yield: 18%).

The reaction scheme and results of NMR analysis and HRMS analysis are as follows:

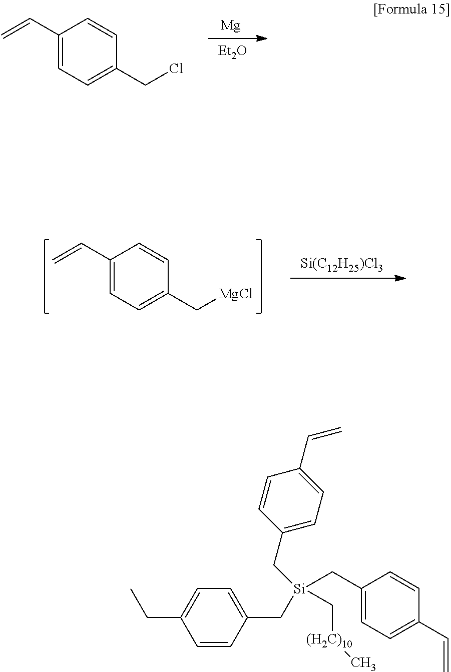

¹H-NMR (CDCl₃): δ (ppm) 7.26 (d, 6H, J=7.68 Hz, Ar—H), 6.91 (d, 6H, J=8.54 Hz, Ar—H), 6.68 (dd, 3H, J=11.1, 17.9 Hz, —CH═CH₂), 5.68 (d, 3H, J=17.9 Hz, —CH═CH₂), 5.17 (d, 3H, J=10.2 Hz, —CH═CH₂), 2.09 (s, 6H, Si—CH₂—Ar), 1.38-1.08 (m, 20H, —CH₂—), 0.88 (t, 3H, J=6.40 Hz, CH₃), 0.53-0.38 (m, 2H, —CH₂—).

HRMS (EI): m/z Calcd for C₃₉H₅₂Si: (M⁺) 548.384, found 548.374.

### EXAMPLE 5

### Synthesis of Dodecyltris(vinylbenzyl)silane Isomeric Mixture (C12-T-mp-Bn-Si)

A 50 mL four-necked flask was charged with magnesium (turning, 0.898 g, 36.9 mmol) and diethyl ether (21.1 mL) under a nitrogen atmosphere, and the mixture was cooled in an ice bath. To the suspension was added dropwise a solution of a 4-(chloromethyl)styrene/3-(chloromethyl)styrene mixture (1:1 (molar ratio), 5.12 g, 33.5 mmol) in diethyl ether (10.5 mL) over an hour. After the mixture was stirred at the same temperature as above for an hour, dodecyltrichlorosilane (3.33 mL, 11.2 mmol) was added dropwise thereto over 20 minutes. The flask was warmed to room temperature, and the mixture was then stirred for 12 hours. Water (15 mL) was added to the reaction solution, and the mixture was stirred for 10 minutes or more to separate an organic phase. Diethyl ether (30 mL) was further added to the water phase, and extraction was performed twice to separate the organic phase. The organic phases obtained from these extractions were combined. The combined organic phases were dried over magnesium sulfate and filtered. The filtrate was concentrated under reduced pressure to give a crude product. The crude product was purified by silica gel column chromatography (mobile phase: n-hexane) to give 0.319 g of a dodecyltris(vinylbenzyl)silane isomeric mixture (C12-T-mp-Bn-Si) as a colorless liquid (yield: 5.2%). From results of NMR analysis, the molar ratio of a 3-vinylbenzyl group to a 4-vinylbenzyl group in the isomeric mixture was estimated to be 1.4:1.6.

The reaction scheme and results of NMR analysis and HRMS analysis are as follows:

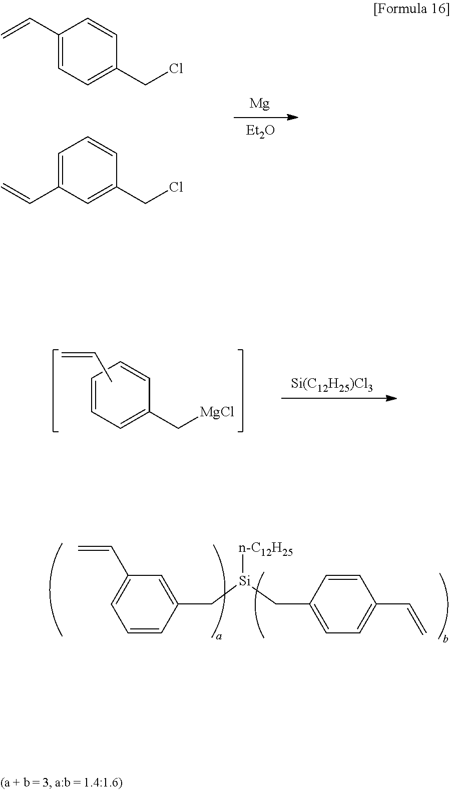

¹H-NMR (CDCl₃): δ (ppm) 7.35-6.81 (m, 12H, Ar—H), 6.74-6.55 (m, 3H, H-5, —CH═CH₂), 5.68 (d, 3H, J=17.1 Hz, —CH═CH₂), 5.20 (d, 1.36H, J=10.2 Hz, —CH═CH₂, m-isomer), 5.17 (d, 1.64H, J=11.1 Hz, —CH═CH₂, o-isomer), 2.10 (s, 6H, Si—CH₂—Ar), 1.38-1.06 (m, 20H, —CH₂—), 0.88 (t, 3H, J=6.83 Hz, CH₃), 0.56-0.39 (m, 2H, —CH₂—).

HRMS (EI): m/z Calcd for C₃₉H₅₂Si: (M⁺) 548.384, found 548.376.

### EXAMPLE 6

### Synthesis of Tetrakis(4-vinylphenyl)silane (C1-Q-p-St-Si)

### Synthesis of Tetrakis(4-formylphenyl)silane

A 300 mL four-necked flask was charged with 4-bromobenzaldehyde dimethyl acetal (12.0 g, 50.9 mmol) and tetrahydrofuran (150 mL) under a nitrogen atmosphere. The solution was cooled to −65° C. or lower, and an n-BuLi/n-hexane solution (2.6 mol/L, 20 mL, 52 mmol) was added dropwise thereto over an hour. The reaction solution was then stirred at −68° C. or lower for two hours. To the resulting suspension was added dropwise tetrachlorosilane (1.14 mL, 9.81 mmol) over 30 minutes, and the mixture was then stirred at the same temperature as above for two hours. The flask was warmed to room temperature, and the mixture was then stirred for 12 hours. The reaction mixture was quenched with hydrochloric acid (2 mol/L, 60 mL), and diethyl ether (50 mL) was added thereto, followed by extraction to separate an organic phase. Diethyl ether (50 mL) was further added to the water phase, and extraction was performed twice to separate the organic phase. The organic phases obtained from these extractions were combined. The combined organic phases were washed with saturated brine (50 mL), dried over magnesium sulfate and filtered. The filtrate was concentrated under reduced pressure to give a crude mixture of acetal/aldehyde. To the crude mixture were added tetrahydrofuran (50 mL) and hydrochloric acid (2 mol/L, 50 mL). The mixture was then heated under reflux for two hours and cooled to room temperature. Thereafter, saturated aqueous sodium hydrogen carbonate solution (100 mL) was added dropwise to the reaction solution. Diethyl ether (50 mL) was added to the reaction solution, and extraction was performed three times to separate the organic phase. The organic phases obtained from these extractions were combined. The combined organic phases were washed with saturated brine (50 mL), dried over magnesium sulfate and filtered. The filtrate was concentrated in vacuo to give a crude product (pale yellow oil). To the crude product was added a mixed solution of ethyl acetate/n-hexane (1:3 (v/v), 40 mL), and the mixture was heated under reflux and then slowly cooled to 0° C. The suspension was filtered, and the resulting solid was dried under reduced pressure to give 2.25 g of tetrakis(4-formylphenyl)silane (yield: 51%).

The reaction scheme and results of NMR analysis are as follows:

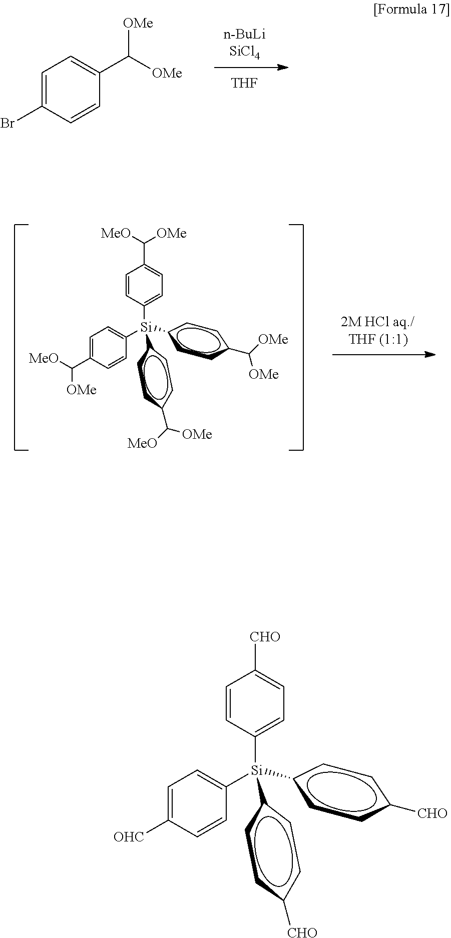

¹H-NMR (CDCl₃): δ (ppm) 10.09 (s, 4H, CHO), 7.94 (d, 8H, J=7.68 Hz, Ar—H), 7.73 (d, 8H, J=8.54 Hz, Ar—H).

### Synthesis of Tetrakis(4-vinylphenyl)silane

A 100 mL four-necked flask was charged with methyltriphenylphosphonium bromide (8.03 g, 22.5 mmol), potassium tert-butoxide (3.03 g, 27.0 mmol) and tetrahydrofuran (34 mL) under a nitrogen atmosphere. The flask was cooled to 0° C., and the reaction mixture was then stirred for five minutes or more. To the reaction mixture was added dropwise a solution of tetrakis(4-formylphenyl)silane (2.10 g, 4.68 mmol) in tetrahydrofuran (34 mL) over 10 minutes. The flask was warmed to room temperature, and the mixture was then stirred for two hours. The reaction mixture was concentrated under reduced pressure at 30° C., and water (50 mL) and diethyl ether (50 mL) were added to the resulting mixture, followed by extraction to separate an organic phase. Diethyl ether (50 mL) was further added to the water phase, followed by extraction to separate the organic phase. The organic phases obtained from these extractions were combined. The combined organic phases were dried over magnesium sulfate and filtered. The filtrate was concentrated under reduced pressure to give a crude mixture. To the crude mixture were added n-hexane (40 mL) and diethyl ether (10 mL), and the mixture was then stirred for 30 minutes. The mixture was filtered through filter paper, and the filtrate was concentrated under reduced pressure to give a crude product. To the crude product were added methanol (10 mL) and 4-tert-butylpyrocatechol (0.6 mg), and the mixture was then stirred at room temperature for 30 minutes. The suspension was filtered, and the resulting solid was dried under reduced pressure to give 0.747 g of tetrakis(4-vinylphenyl)silane (C1-Q-p-St-Si) (yield: 36%).

The reaction scheme and results of NMR analysis are as follows:

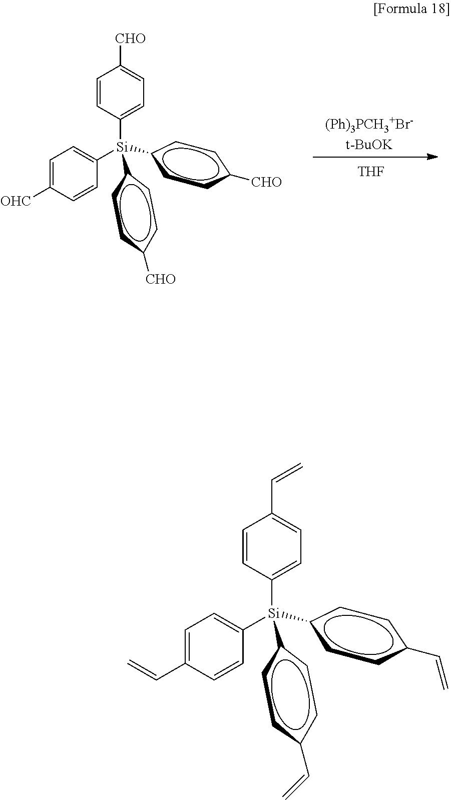

¹H-NMR (CDCl₃): δ (ppm) 7.53 (d, 8H, J=7.68 Hz, Ar—H), 7.41 (d, 8H, J=8.54 Hz, Ar—H), 6.73 (dd, 4H, J=10.7, 17.5 Hz, —CH═CH₂), 5.80 (d, 4H, J=17.9 Hz, —CH═CH₂), 5.29 (d, 4H, J=11.1 Hz, —CH═CH₂).

### EXAMPLE 21

### Synthesis of Dimethylbis(4-vinylphenyl)silane (C1-D-p-St-Si)

### Synthesis of Bis(4-formylphenyl)dimethylsilane

A 500 mL four-necked flask was charged with 4-bromobenzaldehyde dimethyl acetal (24.0 g, 102 mmol) and tetrahydrofuran (300 mL) under a nitrogen atmosphere. The solution was cooled to −65° C. or lower, and an n-BuLi/n-hexane solution (2.6 mol/L, 39 mL, 100 mmol) was added dropwise thereto over an hour. The reaction solution was then stirred at -70° C. or lower for two hours. To the resulting reaction solution was added dropwise dichlorodimethylsilane (4.93 mL, 40.7 mmol) over 40 minutes, and the mixture was then stirred at the same temperature as above for two hours. The flask was warmed to room temperature, and the mixture was then stirred for 12 hours. The reaction mixture was quenched with hydrochloric acid (2 mol/L, 120 mL), and diethyl ether (100 mL) was added thereto, followed by extraction to separate an organic phase. Diethyl ether (100 mL) was further added to the water phase, and extraction was performed twice to separate the organic phase. The organic phases obtained from these extractions were combined. The combined organic phases were washed with saturated brine (100 mL), dried over magnesium sulfate and filtered. The filtrate was concentrated under reduced pressure to give a crude mixture of acetal/aldehyde. To the crude mixture were added tetrahydrofuran (100 mL) and hydrochloric acid (2 mol/L, 100 mL). The mixture was then heated under reflux for two hours and cooled to room temperature. Thereafter, saturated aqueous sodium hydrogen carbonate solution (240 mL) was added dropwise to the reaction solution. Diethyl ether (100 mL) was added to the reaction solution, and extraction was performed three times to separate the organic phase. The organic phases obtained from these extractions were combined. The combined organic phases were washed with saturated brine (100 mL), dried over magnesium sulfate and filtered. The filtrate was concentrated under reduced pressure to give a crude product (pale yellow oil). To the crude product was added a mixed solution of ethyl acetate/n-hexane (1:7 (v/v), 120 mL), and the mixture was heated under reflux and then slowly cooled to 0° C. The suspension was filtered, and the resulting solid was dried under reduced pressure to give 8.40 g of bis(4-formylphenyl)dimethylsilane (yield: 77%).

The reaction scheme and results of NMR analysis are as follows:

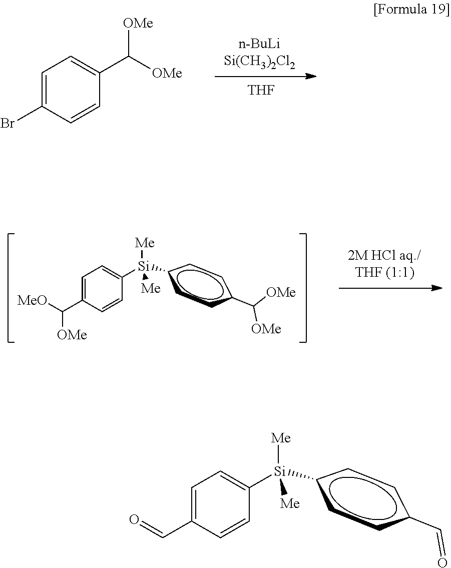

¹H-NMR (CDCl₃): δ (ppm) 10.03 (s, 2H, CHO), 7.86 (d, 4H, J=7.68 Hz, Ar—H), 7.68 (d, 4H, J=8.54 Hz, Ar—H), 0.64 (s, 6H, Si—CH₃).

### Synthesis of Dimethylbis(4-vinylphenyl)silane

A 500 mL four-necked flask was charged with methyltriphenylphosphonium bromide (25.6 g, 71.7 mmol) and tetrahydrofuran (128 mL) under a nitrogen atmosphere. The flask was cooled to 0° C., and potassium tert-butoxide (9.03 g, 80.5 mmol) was then added to the suspension. The reaction mixture was stirred at the same temperature as above for five minutes or more. To the reaction mixture was added dropwise a solution of bis(4-formylphenyl)dimethylsilane (8.00 g, 29.8 mmol) in tetrahydrofuran (128 mL) over 20 minutes. The flask was warmed to room temperature, and the mixture was then stirred for two hours. 4-tert-Butylpyrocatechol (0.60 mg) was added to the reaction mixture and then concentrated under reduced pressure at 30° C. Water (200 mL) and diethyl ether (200 mL) were added to the resulting mixture, followed by extraction to separate an organic phase. Diethyl ether (200 mL) was further added to the water phase, followed by extraction to separate the organic phase. The organic phases obtained from these extractions were combined. The combined organic phases were dried over magnesium sulfate and filtered. The filtrate was concentrated under reduced pressure to give a crude mixture. To the crude mixture were added n-hexane (160 mL) and diethyl ether (40 mL), and the mixture was then stirred for 30 minutes. The mixture was filtered through filter paper, and the filtrate was concentrated under reduced pressure to give a crude product. The crude product was purified by silica gel column chromatography (mobile phase: n-hexane) to give 7.27 g of dimethylbis(4-vinylphenyl)silane (C1-D-p-St-Si) as a colorless liquid (yield: 92%).

The reaction scheme and results of NMR analysis and HRMS analysis are as follows:

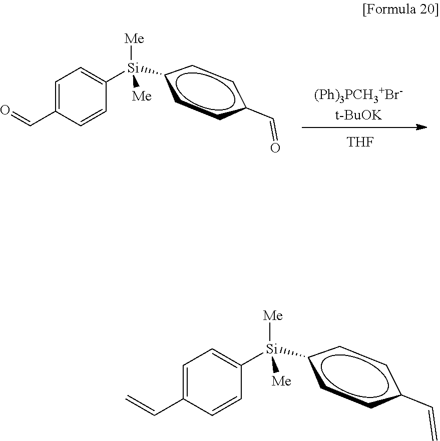

¹H-NMR (CDCl₃): δ (ppm) 7.48 (d, 4H, J=8.54 Hz, Ar—H), 7.38 (d, 4H, J=7.68 Hz, Ar—H), 6.71 (dd, 2H, J=11.1, 17.9 Hz, —CH═CH₂), 5.77 (d, 2H, J=17.1 Hz, —CH═CH₂), 5.25 (d, 2H, J=10.2 Hz, —CH═CH₂), 0.54 (s, 6H, Si—CH₃).

HRMS (EI): m/z Calcd for C₁₈H₂₀Si: (M⁺) 264.133, found 264.131.

### EXAMPLE 31

A commercially available silane coupling agent, trimethoxyvinylsilane (TMVS, manufactured by TCI), was prepared as an organosilicon compound for comparison.

### EXAMPLE 32

A commercially available silane coupling agent, triethoxyvinylsilane (TEVS, manufactured by TCI), was prepared as an organosilicon compound for comparison.

### Evaluation and Result

Using the organosilicon compounds obtained or prepared in Examples 1 to 3, 21, 31 and 32, samples for evaluation were prepared according to the above-described [Method of Preparing Sample for Evaluation (Cured Film Product)] and evaluated. The evaluation results are shown in Tables 1 to 3.

TABLE 1

| | Example 1 | Example 21 |
|---|---|---|
| Organosilicon compound | C1-T-p-St-Si | C1-D-p-St-Si |
| | 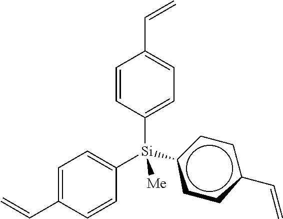 | 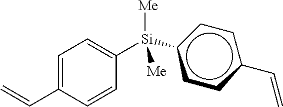 |
| Modified PPE | SA-9000 | SA-9000 |
| Evaluation of | | |
| cured film product | | |
| Dk @ 10 GHz | 2.65 | 2.63 |
| Df @ 10 GHz | 0.0028 | 0.0029 |
| CTE [ppm/° C.] | — | 43 |
| Tg [° C.] | — | 233 |

TABLE 2

| | Example 2 | Example 3 | |
|---|---|---|---|
| Organosilicon compound | C12-T-p-St-Si | C12-T-m-St-Si | |
| | 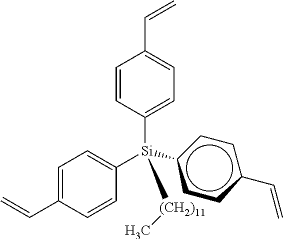 | 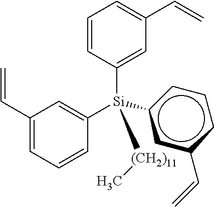 | |
| Modified PPE | SA-9000 | SA-9000 | OPE-2st |
| Evaluation of | | | |
| cured film product | | | |
| Dk @ 10 GHz | 2.63 | 2.49 | 2.59 |
| Df @ 10 GHz | 0.0024 | 0.0021 | 0.0019 |
| CTE [ppm/° C.] | 55 | 55 | 57 |
| Tg [° C.] | 219 | 217 | 212 |

TABLE 3

| | Example 31 | | Example 32 | |
|---|---|---|---|---|
| | Organosilicon compound | | | |
| | TMVS | | TEVS | |
| Evaluation of | Modified PPE | | | |
| cured film product | SA-9000 | OPE-2st | SA-9000 | OPE-2st |
| Dk @10 GHz | 2.64 | 2.76 | 2.66 | 2.71 |
| Df @10 GHz | 0.0056 | 0.0076 | 0.0100 | 0.0125 |
| CTE [ppm/° C.] | 48.7 | 57.9 | 59.4 | 69.5 |
| Tg [° C.] | 232 | 238 | 214 | 194 |

### Summary of Result

In Examples 1 to 3, a cured film product was obtained using a tri- or higher functional organosilicon compound (an organosilicon compound represented by the formula (1TQ)).

In Example 21, a cured film product was obtained using a bifunctional organosilicon compound for comparison.

In Examples 31 and 32, a cured film product was obtained using a silane coupling agent, an organosilicon compound for comparison.

In Examples 1 to 3 and 21, the dielectric dissipation factor (D_{f}) under high-frequency conditions could be effectively reduced as compared with Examples 31 and 32 in which a silane coupling agent was used.

From comparison between Example 1 and Example 21, it was found that the dielectric dissipation factor (D_{f}) under high-frequency conditions can be reduced more effectively by using a tri- or higher functional organosilicon compound as a crosslinking agent.

In Examples 1 to 3, it was possible to obtain a cured film product with effectively reduced dielectric dissipation factor (D_{f}) under high-frequency conditions, sufficiently low coefficient of thermal expansion (CTE) and sufficiently high glass transition temperature (Tg).

### EXAMPLE 101

The bifunctional methacrylic modified PPE (SA9000), the organosilicon compound synthesized in Example 1, dicumyl peroxide as a radical polymerization initiator, spherical silica as an inorganic filler and toluene were mixed in a mass ratio of 7:3:0.1:10:10 and stirred at room temperature to prepare a curable composition (varnish).

The resulting curable composition (varnish) was impregnated into a glass cloth (E glass, #2116) as a fibrous substrate, followed by heating at 130° C. for five minutes to semi-cure the curable composition, thereby obtaining a prepreg.

Two sheets of the obtained prepreg were stacked and sandwiched between a pair of copper foils, and the resulting temporary multilayer body was heated and pressed under the conditions of 200° C., 1.5 hours, and 3 MPa to produce a metal clad laminate.

The present invention is not limited to the above embodiments and Examples, and the design can be modified as appropriate without departing from the gist of the present invention.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A crosslinking agent represented by the following formula (1TQ): 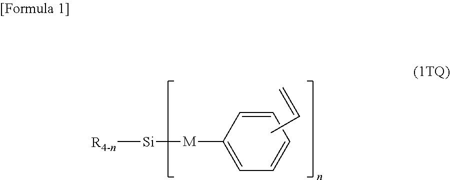
wherein M is a single bond or an optionally substituted alkylene group having 1 to 20 carbon atoms; the benzene ring optionally has a substituent; the vinyl group is attached to the benzene ring at any position; n is an integer of 3 or 4; and R is a hydrogen atom, a hydroxy group or an organic group, and an atom attached to Si is C in a case where R is an organic group.

2. The crosslinking agent according to claim 1, wherein R is an optionally substituted alkyl group having 1 to 18 carbon atoms.

3. The crosslinking agent according to claim 1, wherein M is a single bond or an alkylene group having 1 to 4 carbon atoms.

4. The crosslinking agent according to claim 1, which is for a curable composition used in production of a prepreg, a metal clad laminate or a wiring board.

5. A curable composition comprising: the crosslinking agent according to claim 1; and a curable compound having two or more crosslinkable functional groups capable of crosslinking with the crosslinking agent.

6. A prepreg comprising: a fibrous substrate and a semi-cured or cured product of the curable composition according to claim 5.

7. A multilayer body comprising: a substrate; and a curable composition layer comprising the curable composition according to claim 5.

8. A multilayer body comprising: a substrate; and a (semi-)cured product-containing layer comprising a semi-cured or cured product of the curable composition according to claim 5.

9. The multilayer body according to claim 7, wherein the substrate is a resin film or metal foil.

10. The multilayer body according to claim 8, wherein the substrate is a resin film or metal foil.

11. A metal clad laminate comprising: an insulating layer comprising a cured product of the curable composition according to claim 5; and metal foil.

12. A wiring board comprising: an insulating layer comprising a cured product of the curable composition according to claim 5; and wiring.
